(19) United States
(12) Patent Application Publication
(10) Pub. No.: US 2025/0072005 A1
(43) Pub. Date: Feb. 27, 2025

(54) SEMICONDUCTOR DEVICE

(71) Applicant: SAMSUNG ELECTRONICS CO., LTD., Suwon-si (KR)

(72) Inventors: Kilho LEE, Suwon-si (KR); Yongjae Lee, Suwon-si (KR)

(73) Assignee: SAMSUNG ELECTRONICS CO., LTD., Suwon-si (KR)

(21) Appl. No.: 18/629,542

(22) Filed: Apr. 8, 2024

(30) Foreign Application Priority Data
Aug. 21, 2023 (KR) 10-2023-0109063

(51) Int. Cl. H10B 61/00; B64D 47/00; H01L 25/065; H10B 80/00

(52) U.S. Cl. CPC H10B 61/00; H01L 25/0652; H01L 25/0657; H10B 80/00; B64D 47/00; H01L 2225/06517; H01L 2225/06572

(57) ABSTRACT

Provided is a semiconductor device including a logic region including a circuit, a first memory region controlled by the logic region and having a first storage capacity, the first memory region including a plurality of first memory cells, and a second memory region controlled by the logic region and having a second storage capacity greater than the first storage capacity, the second memory region including a plurality of second memory cells, wherein each of the plurality of first memory cells and each of the plurality of second memory cells includes a magnetic memory element, and wherein an operating speed of the first memory region is faster than an operating speed of the second memory region.

### CROSS-REFERENCE TO RELATED APPLICATION

This application claims priority to Korean Patent Application No. 10-2023-0109063 filed on Aug. 21, 2023 in the Korean Intellectual Property Office, the disclosure of which is incorporated herein by reference in its entirety.

### BACKGROUND

Embodiments of the present disclosure relate to a semiconductor device.

Semiconductor devices may include a logic region in which circuits performing calculations are arranged and a memory region storing data. Semiconductor devices may be applied to various fields and may also be applied to aircraft operating at high altitudes or artificial satellites launched into earth orbit. When semiconductor devices are applied to aircraft, artificial satellites, etc., the semiconductor devices may be significantly affected by cosmic rays, and problems, such as loss of data stored in memory regions thereof, may arise.

### SUMMARY

One or more embodiments provide a semiconductor device in which a memory region storing data is realized as a magnetic memory device, thereby ensuring reliability when applied to aircraft operating at high altitudes or artificial satellites operating in a space environment, etc., in spite of the influence of cosmic rays.

According to an aspect of an example embodiment, there is provided a semiconductor device including a logic region including a circuit, a first memory region controlled by the logic region and having a first storage capacity, the first memory region including a plurality of first memory cells, and a second memory region controlled by the logic region and having a second storage capacity greater than the first storage capacity, the second memory region including a plurality of second memory cells, wherein each of the plurality of first memory cells and each of the plurality of second memory cells includes a magnetic memory element, and wherein an operating speed of the first memory region is faster than an operating speed of the second memory region.

According to another aspect of an example embodiment, there is provided a semiconductor device including a logic region including a semiconductor substrate, a front end of line (FEOL) region including semiconductor elements on the semiconductor substrate, and a back end of line (BEOL) region including wiring patterns connecting at least some of the semiconductor elements to each other, a first memory region including a plurality of first memory cells, and a second memory region including a plurality of second memory cells different from the plurality of first memory cells, wherein the logic region including a first region and a second region in different locations in a direction parallel to an upper surface of the semiconductor substrate, wherein a density of the wiring patterns in the BEOL region in the first region is higher than a density of the wiring patterns in the BEOL region in the second region, and wherein the first region is closer to the first memory region than the second memory region.

According to another aspect of an example embodiment, there is provided a semiconductor device including a logic region including a core that includes a plurality of intellectual property (IP) blocks, and a plurality of cache memories, a first memory region being a dynamic memory, and a second memory region being a storage and having a storage capacity greater than a storage capacity of the first memory region, wherein the plurality of cache memories include an L1 cache, an L2 cache, and an L3 cache, and the L3 cache, and wherein the first memory region and the second memory region are a magnetic memory device.

### BRIEF DESCRIPTION OF DRAWINGS

The above and other aspects, features, and advantages of embodiments will be more clearly understood from the following detailed description, taken in conjunction with the accompanying drawings, in which:

FIGS. 1 and 2 are diagrams illustrating an operating environment of a semiconductor device according to an example embodiment;

FIGS. 3, 4, and 5 are block diagrams schematically illustrating semiconductor devices according to example embodiments;

FIGS. 6 to 9 are schematic diagrams of semiconductor devices according to example embodiments;

FIG. 10 is a diagram schematically illustrating a memory cell included in a semiconductor device according to an example embodiment;

FIG. 11 is a diagram schematically illustrating a memory cell included in a semiconductor device according to an example embodiment;

FIG. 12 is a diagram schematically illustrating a semiconductor device according to an example embodiment;

FIGS. 13 and 14 are diagrams schematically illustrating a semiconductor device according to an example embodiment; and

FIGS. 15, 16, 17, and 18 are diagrams schematically illustrating semiconductor devices according to example embodiments.

### DETAILED DESCRIPTION

Hereinafter, example embodiments will be described with reference to the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

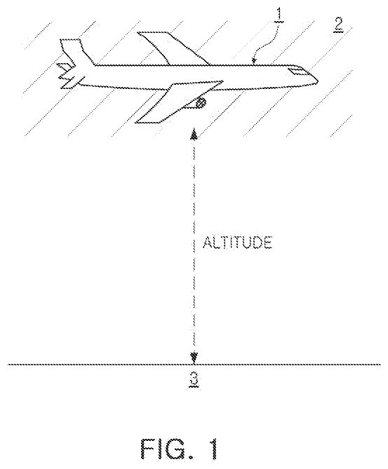

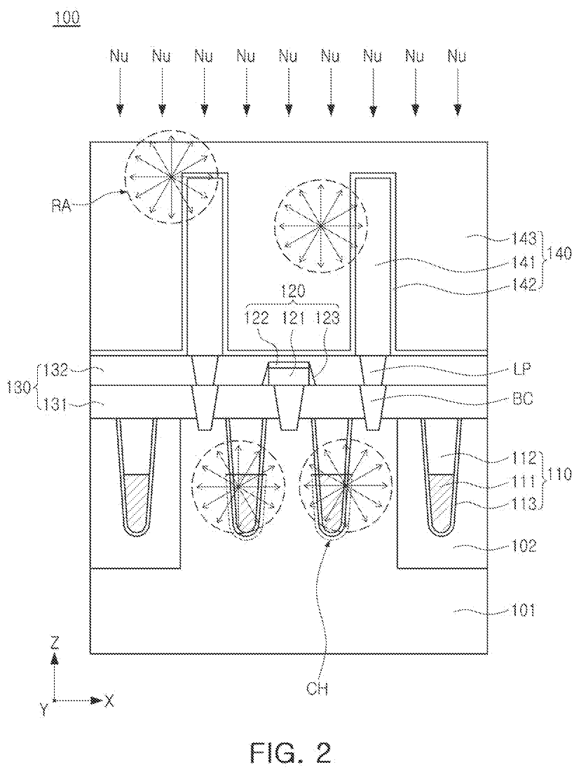

FIGS. 1 and 2 are diagrams illustrating an operating environment of a semiconductor device according to an example embodiment.

First, according to the example embodiment illustrated in FIG. 1, a semiconductor device produced and shipped from a production line may be applied to an aircraft 1 operating at high altitudes. The aircraft 1 is mainly selected as a unit of transportation to transport passengers or goods overseas, and although aircraft may be more expensive compared to other units of transportation, aircraft have the advantage of enabling relatively fast transportation.

However, the aircraft 1 may fly at a predetermined altitude above the ground 3, and therefore may be relatively significantly affected by the cosmic rays 2 compared to units of land and sea transportation. The intensity of the cosmic rays 2 to which the aircraft 1 is exposed may be determined depending on the latitude and longitude of the route along which the aircraft 1 moves and the altitude of the aircraft 1.

For example, thermal neutrons, fast neutrons, etc. may be generated by cosmic rays, and at least some of the materials included in the semiconductor device applied to the aircraft 1 may absorb neutrons, resulting in nuclear fission. As a result of nuclear fission, particles may be generated. The generated particles may move within the semiconductor device and may collide with silicon included in a semiconductor element to cause damage, and the damage may cause vacancy defects. Due to vacancy defects, the characteristics of the semiconductor element, such as resistance of the semiconductor element, may change, which may cause defects in the semiconductor element and semiconductor devices including the semiconductor element.

In addition, loss of stored data may occur due to the influence of cosmic rays. For example, the semiconductor device applied to the aircraft 1 may include a memory region for storing data, and the memory region may be implemented as a charge-based memory device, for example, dynamic random access memory (DRAM), NAND flash memory, etc. In such charge-based memory devices, data is recorded by storing or removing charges, but problems, such as loss of stored charges by cosmic rays, may occur.

In an example embodiment, the memory region included in the semiconductor device may be implemented as a magnetic memory device so that the semiconductor device may operate with relatively high reliability even in an environment in which cosmic rays are relatively strong. For example, in a semiconductor device applied to equipment, such as an artificial satellite or a space station, operating in the aircraft 1 or an environment in which cosmic rays 2 are strong similar to the aircraft 1, a dynamic memory region and a storage region may be implemented as a magnetic memory device. Accordingly, data loss due to the influence of the cosmic rays 2, etc. may be minimized, thereby improving the reliability of the semiconductor device.

FIG. 2 may be a diagram illustrating the influence of cosmic rays on the memory region 100 of the semiconductor device. In an example embodiment illustrated in FIG. 2, the memory region 100 included in the semiconductor device may be implemented as a DRAM device. FIG. 2 may be a cross-sectional view illustrating a memory cell included in the memory region 100. For example, the memory cell may include a transistor and a capacitor.

Referring to FIG. 2, the memory region 100 of the semiconductor device may include a substrate 101 including a semiconductor material, a gate structure 110, a bit line structure 120, an interlayer insulating layer 130, and a capacitor 140. An isolation region 102 defining an active region may be formed of an insulating material in the substrate 101, and the gate structure 110 may be formed as a structure embedded in the substrate 101.

The gate structure 110 may include a gate electrode 111, a capping layer 112, and a gate insulating layer 113. According to example embodiments, the gate electrode 111 may have a multilayer structure formed of a plurality of different conductive materials, for example, metal materials, and may provide a word line. The capping layer 112 may be formed of polysilicon, silicon nitride, silicon oxide, silicon oxynitride, silicon carbonitride, silicon oxycarbonitride, etc. The gate insulating layer 113 may be formed of a high-k material having permittivity higher than permittivity of silicon oxide or silicon nitride. As illustrated in FIG. 2, a channel region CH may be formed around the gate electrode 111.

The interlayer insulating layer 130 may be disposed on the substrate 101. The interlayer insulating layer 130 may include a lower interlayer insulating layer 131 and an upper interlayer insulating layer 132. The active region adjacent to the gate structure 110 may be connected to a buried contact BC penetrating through the lower interlayer insulating layer 131, and the buried contact BC may be connected to a landing pad LP penetrating through the upper interlayer insulating layer 132. The buried contact BC connected to the active region between adjacent gate structures 110 may be connected to the bit line structure 120. The bit line structure 120 may include a conductive layer 121, a capping layer 122, and a spacer 123.

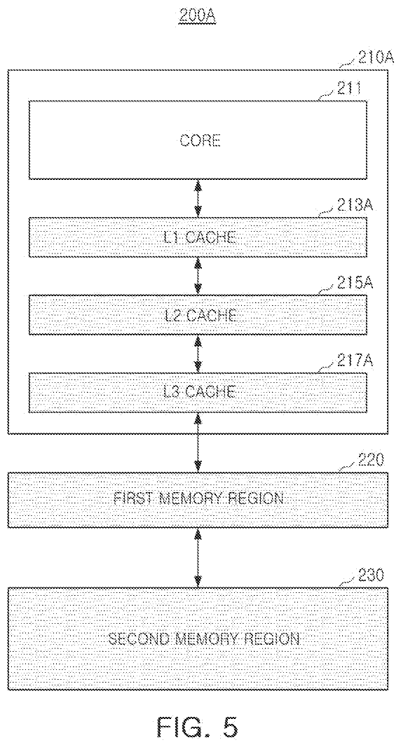

The capacitor 140 extending in a first direction (a Z-axis direction) may be connected to the top of the landing pad LP. The capacitor 140 may include a lower electrode 141, a capacitor dielectric layer 142, and an upper electrode 143, and the lower electrode 141 may have a shape other than a pillar shape illustrated in FIG. 5. The lower electrode 141 may be formed of a metal, a metal compound, etc., and the upper electrode may be formed of a doped semiconductor material, such as silicon germanium (SiGe).

When relatively strong cosmic rays exist around the memory region 100, neutrons (Nu) caused by the cosmic rays may be incident on the memory region 100. Neutrons (Nu) incident on the memory region 100 may be absorbed by a material having a relatively high neutron absorption rate, such as boron-10, among the materials included in the memory region 100, thereby causing a nuclear fission reaction RA.

For example, as illustrated in FIG. 2, a nuclear fission reaction RA occurs in silicon germanium constituting the upper electrode 143 of the capacitor 140, and as a result, predetermined particles may be generated. In addition, a nuclear fission reaction RA may occur in the substrate 101 including a semiconductor material, and particles may be generated as a result. While particles generated by nuclear fission reaction RA move, the particles may collide with the nuclei of semiconductor materials, such as silicon and silicon germanium, causing damage and resulting in defects.

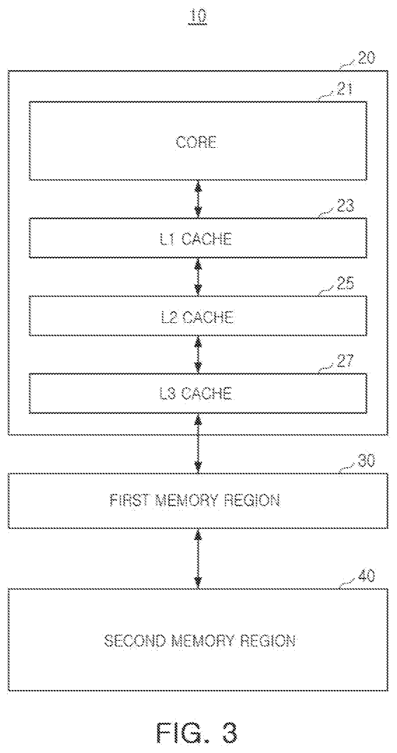

FIGS. 3 to 5 are block diagrams schematically illustrating semiconductor devices according to example embodiments.

First, FIG. 3 is a block diagram schematically illustrating a semiconductor device 10 according to a related example. In the related example, the semiconductor device 10 may include a core region 20, a first memory region 30, and a second memory region 40, and the core region 20 may include a core 21, L1 cache 23, L2 cache 25, and L3 cache 27. The first memory region 30 may operate as a dynamic memory, and the second memory region 40 may operate as a storage.

The second memory region 40 may have a relatively large storage capacity compared to a storage capacity of the first memory region 30, and the first memory region 30 may have a relatively large storage capacity compared to storage capacities of cache memories 23, 25, and 27 included in the core region 20. Circuits that perform various operations may be disposed in the core 21. For example, a central processing unit (CPU), a graphics processing unit (GPU), etc. may be disposed in the core 21.

In the semiconductor device 10 according to the related example, the first memory region 30 and the second memory region 40, as well as the cache memories 23, 25, and 27, may store data based on charge or may execute an operation of reading stored data. For example, each of the memory cells in the first memory region 30 may include a capacitor, and data may be recorded by charging a charge in the capacitor.

However, when data is stored based on a charge as in the related example, the application field of the semiconductor device 10 may be limited. For example, when the semiconductor device 10 is applied to an aircraft operating at a relatively high altitude, an artificial satellite operating outside the atmosphere, a space shuttle, etc., the stored data may be accidentally lost and the semiconductor device 10 may malfunction under the relatively strong influence of cosmic rays compared to an environment close to the earth's surface.

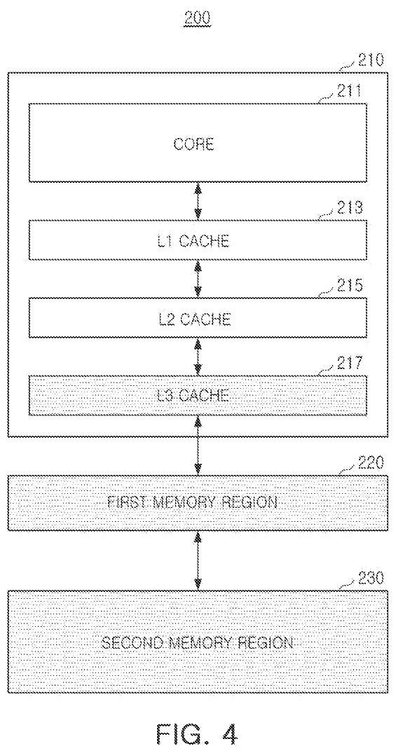

In an example embodiment, the above problem may be solved by implementing at least some of the memories included in a semiconductor device 200 as a magnetic memory device having high reliability even in an environment affected by cosmic rays. For example, in the semiconductor device 200 according to the example embodiment illustrated in FIG. 4, a first memory region 220, a second memory region 230, and an L3 cache 217 inside a logic region 210 may be implemented as a magnetic memory device.

According to example embodiments, a part of the first memory region 220, the second memory region 230, and the L3 cache 217 may be replaced with a magnetic memory device. In this case, the first memory region 220, the second memory region 230, and the L3 cache 217 may each have a hybrid structure including a region implemented as a magnetic memory device and a region implemented as a charge-based memory device.

Each of the first memory region 220, the second memory region 230, and the L3 cache 217 may be implemented as a magnetic memory device, such as a spin transfer torque (STT)-magnetoresistive random-access memory (MRAM), spin orbit torque (SOT)-MRAM, or RACETRACK. For example, each of a plurality of first memory cells included in the first memory region 220 and a plurality of second memory cells included in the second memory region 230 may be implemented as an STT-MRAM cell. Each of the plurality of first memory cells may be implemented as a first STT-MRAM cell including a first magnetic memory element, and each of the plurality of second memory cells may be implemented as a second STT-MRAM cell including a second magnetic memory element.

Specifications required for the first memory region 220 and the second memory region 230 may be different, and thus, the first STT-MRAM cell and the second STT-MRAM cell may have different characteristics. For example, the perpendicular magnetic anisotropy of the first magnetic memory element included in the first STT-MRAM cell may be lower than the perpendicular magnetic anisotropy of the second magnetic memory element included in the second STT-MRAM cell. In addition, the size of each of the plurality of first memory cells may be smaller than the size of each of the plurality of second memory cells. This may be because the first memory region 220 requires a relatively fast operating speed compared to the second memory region 230 and the second memory region 230 requires relatively large storage capacity, high integration, and good retention characteristics compared to the first memory region 220.

In an example embodiment illustrated in FIG. 4, the L3 cache 217 may be implemented as an STT-MRAM cell or a SOT-MRAM cell. Each of the memory cells included in the L3 cache 217 may have a faster operating speed than speeds of the memory cells included in each of the first memory region 220 and the second memory region 230. For example, each of the memory cells included in the L3 cache 217 may be implemented as an STT-MRAM cell including a magnetic memory element having lower perpendicular magnetic anisotropy than that of each of the first memory cells included in the first memory region 220.

In an example embodiment illustrated in FIG. 4, each of the L1 cache 213 and L2 cache 215 included in the logic region 210 along with the core 211 may be implemented as a charge-based memory device, for example, static random access memory (SRAM) device. However, according to example embodiments, as illustrated in FIG. 5, cache memories 213A, 215A, and 217A included in a logic region 210A may all include magnetic memory devices. A plurality of intellectual property (IP) blocks may be disposed in the core 211.

In the semiconductor device 200A according to an example embodiment illustrated in FIG. 5, all the L1 cache 213A, L2 cache 215A, and L3 cache 217A included in the logic region 210A may include at least one memory cell having a magnetic memory element. For example, at least some of the memory cells included in the L1 cache 213A and the L2 cache 215A may be implemented as SOT-MRAM cells. According to example embodiments, the memory cells included in the L1 cache 213A and the L2 cache 215A may all include magnetic memory elements.

The configuration of the L3 cache 217A and each of the first memory region 220 and the second memory region 230 may be selected in various manners as described above with reference to FIG. 4. Under the conditions in which the L3 cache 217A has a faster operating speed than the first memory region 220 and the second memory region 230 and the second memory region 230 has larger storage capacity and better retention characteristics than the first memory region 220, memory cells included in the L3 cache 217A and each of the first memory region 220 and the second memory region 230 may include magnetic memory devices according to various example embodiments.

According to example embodiments, only some of the memory cells in the L3 cache 217A, the first memory region 220, and the second memory region 230 may be replaced with magnetic memory elements. For example, a portion of the first memory region 220 may be implemented as a magnetic memory device, and the remainder of the first memory region 220 may be implemented as a DRAM device including a transistor and a capacitor. A portion of the second memory region 230 may be implemented as a magnetic memory device, and the remainder of the second memory region 230 may be implemented as a NAND flash device.

For example, each of the first memory cells of the first memory region 220 and the second memory cells of the second memory region 230 may be implemented as an STT-MRAM cell. According to example embodiments, each of the first memory cells in the first memory region 220 may be implemented as an SOT-MRAM cell, and each of the second memory cells in the second memory region 230 may be implemented as an STT-MRAM cell. In addition, each of the first memory cells in the first memory region 220 may be implemented as an SOT-MRAM cell, and each of the second memory cells in the second memory region 230 may be implemented as a RACETRACK element. In addition, each of the first memory cells in the first memory region 220 may be implemented as an STT-MRAM cell, and each of the second memory cells in the second memory region 230 may be implemented as a RACETRACK element.

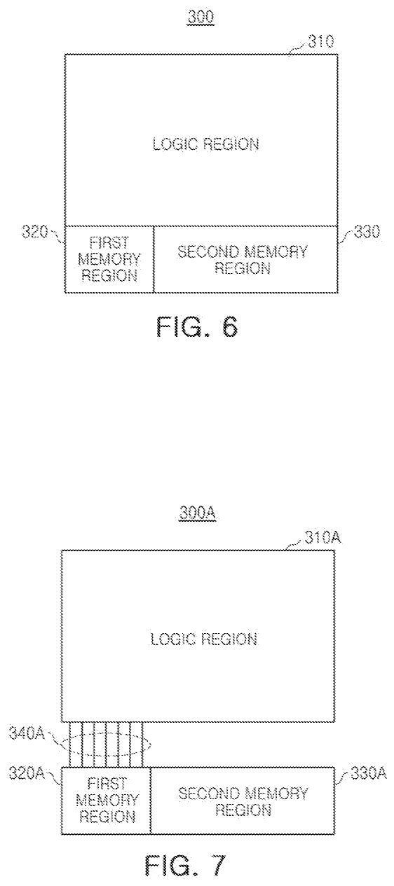

FIGS. 6 to 9 are schematic diagrams of semiconductor devices according to example embodiments.

First, referring to FIG. 6, a semiconductor device 300 according to an example embodiment may include a logic region 310, a first memory region 320, and a second memory region 330. In an example embodiment illustrated in FIG. 6, the semiconductor device 300 including the logic region 310, the first memory region 320, and the second memory region 330 may be included in a single chip. The logic region 310 may include a CPU, GPU, neural processor, etc. that perform various operations, input/output circuits, power circuits, modems, etc.

The first memory region 320 may be implemented with a relatively small storage capacity compared to the second memory region 330, but may require a relatively fast operating speed compared to the second memory region 330. The second memory region 330 may be a storage in which data is maintained regardless of power OFF, etc., and therefore may require a large storage capacity and excellent retention characteristics compared to the first memory region 320.

In an example embodiment, at least a portion of each of the first memory region 320 and the second memory region 330 may be implemented as a magnetic memory device. A magnetic memory device may be used in situations where data loss may occur in a charge-based memory device due to a surrounding environment where cosmic rays, etc. are strongly introduced, and thus the reliability of the semiconductor device 300 may be improved.

In a semiconductor device 300A according to the example embodiment illustrated in FIG. 7, a logic region 310A may be implemented as a separate chip from a first memory region 320A and a second memory region 330A. The logic region 310A may be implemented as one first chip, and the first memory region 320A and the second memory region 330A may be included in a second chip separate from the first chip. The logic region 310A may communicate with the first memory region 320A and exchange data through a plurality of external wirings 340A connecting the first chip to the second chip. However, according to example embodiments, the logic region 310A may exchange data by directly communicating with the second memory region 330A.

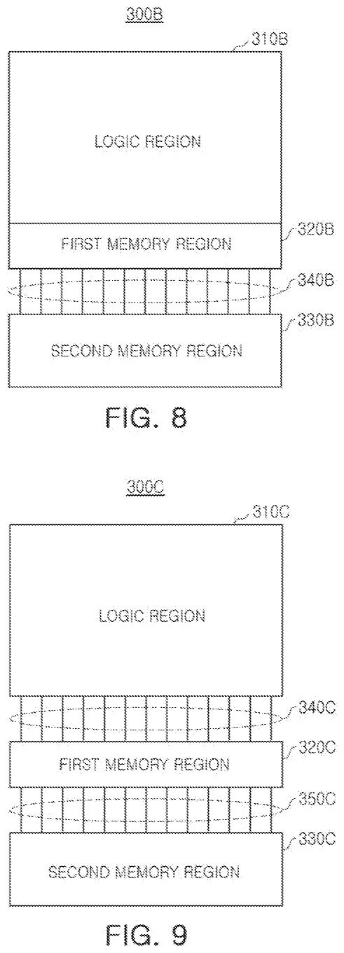

In a semiconductor device 300B according to the example embodiment illustrated in FIG. 8, a logic region 310B and a first memory region 320B may be included in one first chip, and a second memory region 330B may be included in a second chip, different from the first chip. The logic region 310B and the first memory region 320B may communicate with each other and exchange data through a bus inside the first chip. The second memory region 330B may exchange data with the first memory region 320B through a plurality of external wirings 340B. However, according to example embodiments, the logic region 310B may communicate directly with the second memory region 330B.

In a semiconductor device 300C according to the example embodiment illustrated in FIG. 9, a logic region 310C, a first memory region 320C, and a second memory region 330C may be implemented in different chips, respectively. For example, the logic region 310C may be implemented as a first chip, the first memory region 320C may be implemented as a second chip separate from the first chip, and the second memory region 330C may be implemented as a third chip separate from the first chip and the second chip. The logic region 310C and the first memory region 320C may exchange data through a plurality of first external wirings 340C, and the first memory region 320C and the second memory region 330C may exchange data through a plurality of second external wirings 350C. According to example embodiments, additional external wirings directly connecting the logic region 310C to the second memory region 330C may be added.

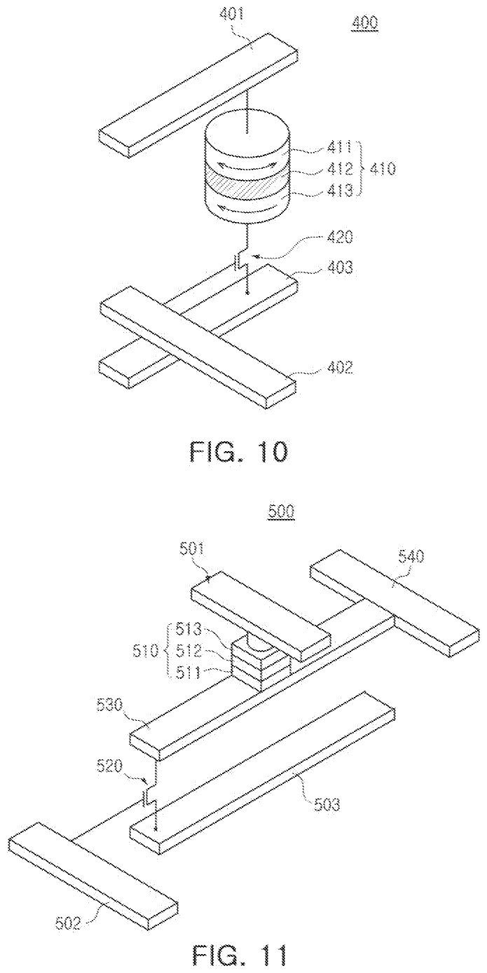

FIG. 10 is a diagram schematically illustrating a memory cell included in a semiconductor device according to an example embodiment.

A memory cell 400 described with reference to FIG. 10 may be an STT-MRAM cell and may include a magnetic memory element 410 and a switch element 420. A first electrode of the switch element 420 may be connected to a first conductive line 401 through a magnetic memory element 410, a gate electrode of the switch element 420 may be connected to the second conductive line 402, and a second electrode of the switch element 420 may be connected to the third conductive line 403. The first conductive line 401 may be allocated as a bit line, the second conductive line 402 may be allocated as a word line, and the third conductive line 403 may be allocated as a source line.

The magnetic memory device 410 may include a free layer 411, a pinned layer 413, and a tunnel layer 412 disposed therebetween. A magnetization direction of the pinned layer 413 is fixed and does not change, and a magnetization direction of the free layer 411 may change in a direction that is the same as or opposite to the magnetization direction of the pinned layer 413 depending on conditions. In order to fix the magnetization direction of the pinned layer 413, an anti-ferromagnetic layer may be further included in the magnetic memory device 410.

For example, by inputting current flowing from the first conductive line 401 to the third conductive line 403 into the magnetic memory element 410, the magnetization direction of the free layer 411 may be set to be the same as the magnetization direction of the pinned layer 413. In this case, resistance of the magnetic memory element 410 may decrease. By inputting current flowing from the third conductive line 403 to the first conductive line 401 into the magnetic memory element 410, the magnetization direction of the free layer 411 may be set to be opposite to the magnetization direction of the pinned layer 413. In this case, the resistance of the magnetic memory element 410 may increase. As such, in the memory cell 400 illustrated in FIG. 10, by controlling the current flowing in the direction, perpendicular to an upper surface of the free layer 413 in the magnetic memory element 410, a magnitude of the resistance of the magnetic memory element 410 may be varied and data may be recorded.

Data recorded by changing the magnetization direction of the free layer 413 in the magnetic memory element 410 may not be lost despite the influence of cosmic rays introduced from the outside. Therefore, a semiconductor device optimized for aircraft, artificial satellites, space shuttles, etc. may be implemented using a magnetic memory device including the memory cell 400 as illustrated in FIG. 10.

As described above, the semiconductor device may include a plurality of memory regions divided according to purposes thereof. For example, the first memory region allocated as a dynamic memory may need to provide relatively fast operating speed, and the second memory region allocated as a storage may need to provide high retention characteristics and large storage capacity. In an example embodiment, each of the memory cells in the first memory region and the second memory region may be implemented as the memory cell 400 according to the example embodiment illustrated in FIG. 10, and the first memory region and the second memory region may be implemented by varying the size and perpendicular magnetic anisotropy characteristics of the memory cell

The memory cell 400 implemented as an STT-MRAM cell, as in the example embodiment illustrated in FIG. 10, may have limitations in reducing the operating speed to 5 ns or less. Therefore, it may be difficult to implement a cache memory included in a logic region in a semiconductor device, especially an L1 cache or an L2 cache, as the memory cell 400 illustrated in FIG. 10. In an example embodiment, not only dynamic memory and storage, but also cache memory inside the logic region may be implemented as a magnetic memory device using a SOT-MRAM cell having an operating speed of 5 ns or less. This will be described in detail with reference to FIG. 11 hereinafter.

FIG. 11 is a diagram schematically illustrating a memory cell included in a semiconductor device according to an example embodiment.

A memory cell 500 illustrated in FIG. 11 may be a SOT-MRAM cell and may include a magnetic memory element 510. The magnetic memory element 510 may include a free layer 511, a tunnel layer 512, and a pinned layer 513. The pinned layer 513 may be connected to a first conductive line 501 provided as a bit line, and the free layer 511 may be connected to the channel layer 530. One end of the channel layer 530 may be connected to a write line 540, and the channel layer 530 may be connected to a work electrode of a switch element 520. A gate electrode of the switch element 520 may be connected to a second conductive line 502 provided as a word line, and the other electrode of the switch element 520 may be connected to a third conductive line 503 provided as a source line. The switch element 520 is an element controlling current to the second conductive line 502, and the memory cell 500 may record data using the magnetic memory element 510 alone.

In the memory cell 500 illustrated in FIG. 11, a path through which current flows during a write operation and a path through which current flows during a read operation may be separated. For example, during a write operation, a write current may flow through the channel layer 530 and the write line 540, but the write current may not be input to the bit line 501. During a read operation, a read current may flow through the bit line 501, the magnetic memory element 510, and the channel layer 530. Accordingly, the number of terminals for controlling the memory cell 500 illustrated in FIG. 11 may be greater than the number of terminals for controlling the memory cell 400 described above with reference to FIG. 10.

During a write operation, current flowing through the channel layer 530 and the write line 540 may flow in a direction, parallel to an upper surface of the magnetic memory element 510. Due to the current flowing in the channel layer 530, a spin-orbit coupling force may generated and a magnetization direction of the free layer 511 may change, so that data may be written to the memory cell 500.

Due to such an operating method, an operating speed of the memory cell 500 may be faster than an operating speed of the memory cell 400 described above with reference to FIG. 10. Therefore, the cache memory included in the logic region of the semiconductor device may be implemented as a magnetic memory device including the memory cell 500 illustrated in FIG. 11, and data in the cache memory may be more stably maintained even in an environment where strong cosmic rays are introduced.

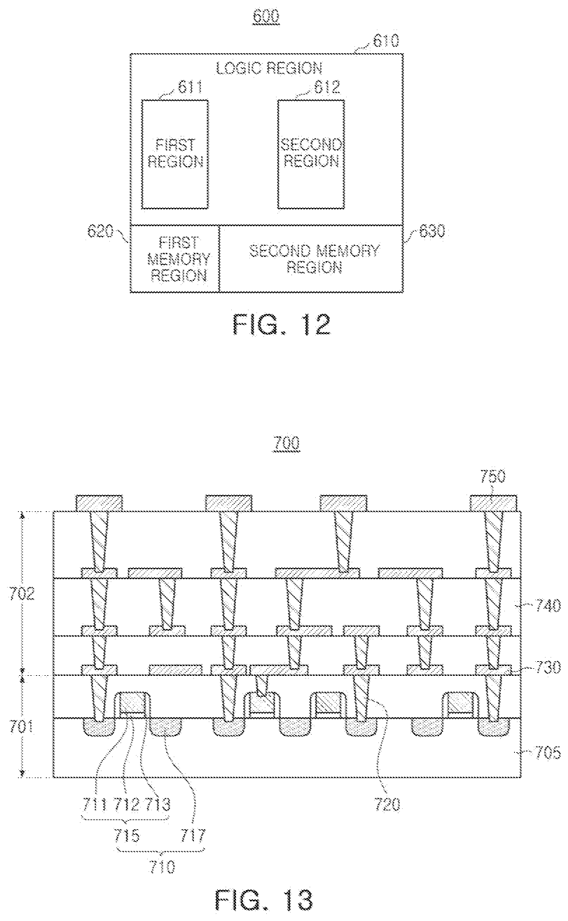

FIG. 12 is a diagram schematically illustrating a semiconductor device according to an example embodiment.

Referring to FIG. 12, a semiconductor device 600 according to an example embodiment may include a logic region 610, a first memory region 620, and a second memory region 630. The logic region 610 may include a first region 611 and a second region 612. Similar to other example embodiments described above, the first memory region 620 may be allocated as a dynamic memory, and the second memory region 630 may be allocated as a storage.

The first region 611 and the second region 612 included in the logic region 610 may include IP blocks performing different functions. For example, the first region 611 may include a CPU, a GPU, a neural processor, etc., and the second region 612 may include a power circuit, an input/output circuit, etc.

Therefore, relatively more complex calculations may be performed in the first region 611 compared to the second region 612, and power consumption in the first region 611 may be higher than power consumption in the second region 612. For example, each of the first region 611 and the second region 612 may include a front end of line (FEOL) region in which semiconductor elements are arranged, and a back end of line (BEOL) region in which wiring patterns connected to the semiconductor elements are arranged, and a density of wiring patterns in the BEOL region of the first region 611 may be higher than a density of wiring patterns in the BEOL region of the second region 612.

Due to this structural difference, more heat may be generated in the first region 611 than in the second region 612 while the logic region 610 is operating. In an example embodiment illustrated in FIG. 12, the first memory region 620 may be disposed to be closer to the first region 611, where heat is generated more easily and more strongly, and the second memory region 630 may be disposed in a position farther away from the first region 611. Accordingly, the possibility of losing data in the second memory region 630 allocated as a storage due to heat generation in the first region 611 of the logic region 610 may be more effectively reduced.

Since the first memory region 620 and the second memory region 630 are implemented as magnetic memory devices, the operating speed of memory cells included in the first memory region 620 may increase as the surrounding temperature increases. Therefore, by arranging the first region 611 and the first memory region 620 adjacent to each other as illustrated in FIG. 12, the effect of further improving the operating speed of the first memory region 620 allocated as a dynamic memory may be obtained.

However, when the semiconductor device 600 is applied to an application in which the first memory region 620 needs to more stably maintain data while the semiconductor device 600 operates, the first memory region 620 and the second memory region 630 may be arranged to be different from the arrangement of FIG. 12. For example, when the semiconductor device 600 is targeted for an application in which the first memory region 620 needs to more stably maintain data, the first region 611 may be disposed to be closer to the second memory region 630 than the first memory region 620.

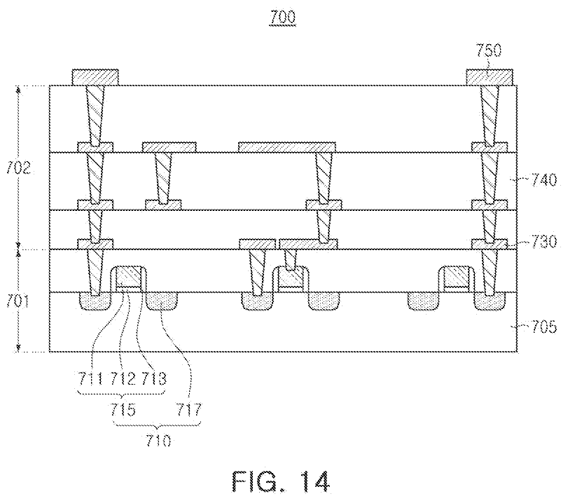

FIGS. 13 and 14 are schematic diagrams of a semiconductor device according to an example embodiment.

Referring to FIGS. 13 and 14, a semiconductor device 700 according to an example embodiment may include a semiconductor substrate 705, a plurality of semiconductor elements 710, a plurality of contacts 720, and a plurality of wiring patterns 730, an interlayer insulating layer 740, and a plurality of pads 750. The semiconductor substrate 705 may include a semiconductor material, such as silicon.

Each of the plurality of semiconductor devices 710 may include a gate structure 715 and an active region 717. The gate structure 715 may include a gate electrode 711, a gate insulating layer 712, and a gate spacer 713. The gate electrode 711 may be formed of a conductive material, such as metal or polysilicon, and the gate insulating layer 712 may be disposed between the gate electrode 711 and the semiconductor substrate 705. The active region 717 may be doped with a P-type impurity or an N-type impurity and may be formed to be adjacent to the gate structure 715 to provide a source region and a drain region.

The plurality of contacts 720 may connect the plurality of semiconductor devices 710 to the plurality of wiring patterns 730 and connect the plurality of wiring patterns 730 to each other. The plurality of wiring patterns 730 may extend in a direction, parallel to an upper surface of the semiconductor substrate 705, and may be embedded in the interlayer insulating layer 740 together with the plurality of contacts 720. The plurality of pads 750 may be formed on an upper surface of the interlayer insulating layer 740.

The semiconductor device 700 may include an FEOL region 701 in which a plurality of semiconductor elements 710 are arranged and a BEOL region 702 in which a plurality of wiring patterns 730 are arranged. The BEOL region 702 may be disposed on the FEOL region 701 in a direction parallel to the upper surface of the semiconductor substrate 705.

FIG. 13 is a cross-sectional view of a first region included in a logic region of the semiconductor device 700, and in which circuits performing complex operations or functions, such as a CPU and a GPU, are arranged, and FIG. 14 may be a cross-sectional view of a second region included in the logic region and in which circuits performing relatively simple operations or functions are arranged. Referring to FIGS. 13 and 14, a density of the plurality of wiring patterns 730 arranged in the first region may be higher than a density of the plurality of wiring patterns 730 arranged in the second region. Accordingly, while the semiconductor device 700 operates, heat generation in the first region may be greater than heat generation in the second region.

In an example embodiment, the arrangement of the logic region and the memory region may be determined by considering the difference in heat generation. For example, when the retention performance of the memory region allocated as a storage is important, the first region may be disposed to be closer to a dynamic memory. When there is a need to retain data in the dynamic memory even for a short period of time, the first region may be disposed to be closer to the storage.

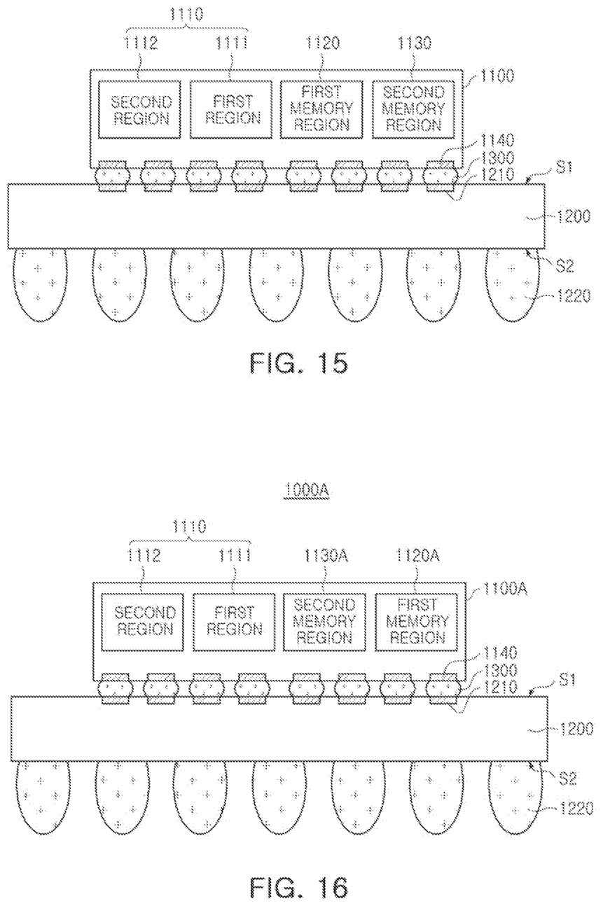

FIGS. 15 to 18 are schematic diagrams of semiconductor devices according to example embodiments.

First, referring to FIG. 15, a semiconductor device 1000 according to an example embodiment may include a semiconductor chip 1100 and a package substrate 1200 on which the semiconductor chip 1100 is mounted. The semiconductor chip 1100 may include a logic region 1110, a first memory region 1120, and a second memory region 1130, and the first memory region 1120 may be allocated as a dynamic memory and the second memory region 1130 may be allocated as a storage.

The semiconductor chip 1100 may include a plurality of pads 1140 formed on one surface, and the plurality of pads 1140 may be physically connected to a plurality of pads 1210 formed on a first surface S1 of the package substrate 1200 by a plurality of bumps 1300. A plurality of bumps 1220 may be arranged on a second surface S2 of the package substrate 1200, and the plurality of bumps 1220 may be connected to another substrate.

The logic region 1110 may include a first region 1111 executing a relatively complex operation or function and a second region 1112 executing a relatively simple operation or function. Accordingly, while the semiconductor device 1000 is operating, more severe heat may be generated in the first region 1111 than in the second region 1112.

In an example embodiment illustrated in FIG. 15, the first region 1111 may be disposed to be closer to the first memory region 1120 than the second memory region 1130. Accordingly, the second memory region 1130, which needs to implement high retention performance, may be protected from heat generated by the first region 1111.

Next, referring to FIG. 16, a semiconductor device 1000A according to an example embodiment may include a semiconductor chip 1100A and a package substrate 1200 on which the semiconductor chip 1100A is mounted. The semiconductor chip 1100A may include a logic region 1110, a first memory region 1120A, and a second memory region 1130A, and the first memory region 1120A may be allocated as a dynamic memory and the second memory region 1130A may be allocated as a storage.

In an example embodiment illustrated in FIG. 16, the first region 1111 may be disposed to be closer to the second memory region 1130A than the first memory region 1120A. For example, when retention performance of a certain level or higher is required in the first memory region 1120A allocated as a dynamic memory, the semiconductor device 1000A may be implemented as illustrated in FIG. 16.

Each of the first memory region 1120A and the second memory region 1130A may be implemented as a magnetic memory device, and may be implemented as an STT-MRAM device, for example. At this time, in order to improve the operating speed of the first memory region 1120A allocated as a dynamic memory, vertical magnetic anisotropy of the magnetic memory device included in each of the memory cells in the first memory region 1120A may be set to be lower than the perpendicular magnetic anisotropy of the magnetic memory device included in each of the memory cells in the second memory region 1130A.

Therefore, the retention performance of the second memory region 1130A may be higher than that of the first memory region 1120A. By disposing the second memory region 1130A, having better retention performance, to be closer to the first region 1111 and disposing the first memory region 1120A to be farther away from the first region 1111, retention performance that is greater than or equal to a certain level may be secured even in the dynamic memory.

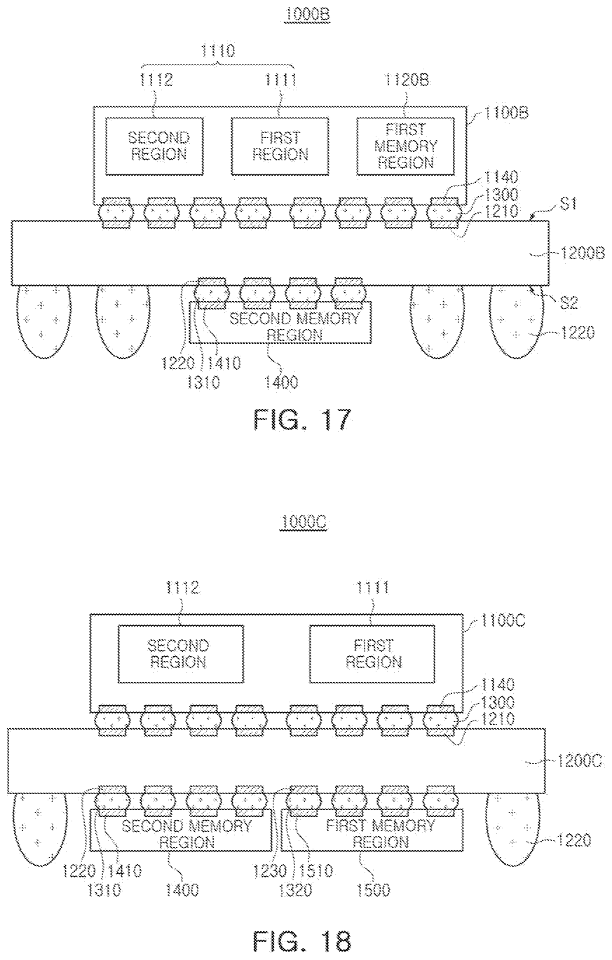

Next, referring to FIG. 17, a semiconductor device 1000B according to an example embodiment may include a first semiconductor chip 1100B, a second semiconductor chip 1400, and a package substrate 1200B on which the first semiconductor chip 1100B and the second semiconductor chip 1400 are mounted. The first semiconductor chip 1100B may include a logic region 1110 and a first memory region 1120B, and a second memory region may be implemented in the second semiconductor chip 1400. The second semiconductor chip 1400 may include a plurality of pads 1410, and the plurality of pads 1410 may be physically connected to a plurality of pads 1220 formed on a second surface S2 of the package substrate 1200B through a plurality of bumps 1310.

As previously described, the first memory region 1120B may be allocated as a dynamic memory, and the second memory region may be allocated as a storage. In the example embodiment illustrated in FIG. 17, the second memory region that may need to provide a relatively large storage capacity may be implemented in a separate second semiconductor chip 1400 divided from the logic region 1110, and the second memory region 1400 may be mounted on the second surface S2 of the package substrate 1200B. Therefore, the influence of heat generated by the logic region 1110 inside the first semiconductor chip 1100B mounted on the first surface S1 on the second memory region may be effectively reduced, and the retention performance of the second memory region may be secured more effectively.

Referring to FIG. 18, a semiconductor device 1000C according to an example embodiment may include a first semiconductor chip 1100C, a second semiconductor chip 1400, a third semiconductor chip 1500, and a package substrate 1200C. The first semiconductor chip 1100C may include a first region 1111 and a second region 1112 providing a logic region, and a first memory region allocated as a dynamic memory may be provided by the third semiconductor chip 1500 and a second memory region allocated as a storage may be provided by the second semiconductor chip 1400.

The second semiconductor chip 1400 may include a plurality of pads 1410, and the plurality of pads 1410 may be physically connected to the plurality of pads 1220 formed on a second surface S2 of the package substrate 1200C through a plurality of bumps 1310. Similarly, the third semiconductor chip 1500 may include a plurality of pads 1510, and the plurality of pads 1510 may be physically connected to a plurality of pads 1230 formed on the second surface S2 of the package substrate 1200C through a plurality of bumps 1320.

In an example embodiment illustrated in FIG. 18, the second semiconductor chip 1400 and the third semiconductor chip 1500 may be mounted on the second surface S2 of the package substrate 1200C, and the first semiconductor chip 1100C providing a logic region may be mounted on the first surface S1. Accordingly, the influence of heat generated during the operation of the first semiconductor chip 1100C mounted on a first surface S1 on each of the first memory region, which is a dynamic memory, and the second memory region, which is a storage, may be effectively reduced and the reliability of the semiconductor device 1000C may be improved.

According to an example embodiment, among memory regions included in the semiconductor device, the first memory region operating as a dynamic memory and the second memory region operating as a storage may be implemented as a magnetic memory device. Therefore, unlike memory devices operating based on charges, data loss that may occur due to the influence of cosmic rays may be minimized and the semiconductor device that may be applied even in environments where the influence of cosmic rays is severe may be implemented.

While example embodiments have been illustrated and described above, it will be apparent to those skilled in the art that modifications and variations could be made without departing from the scope of the present inventive concept as defined by the appended claims and their equivalents.

1. A semiconductor device comprising:
a logic region comprising a circuit;
a first memory region controlled by the logic region and having a first storage capacity, the first memory region comprising a plurality of first memory cells; and
a second memory region controlled by the logic region and having a second storage capacity greater than the first storage capacity, the second memory region comprising a plurality of second memory cells,
wherein each of the plurality of first memory cells and each of the plurality of second memory cells comprises a magnetic memory element, and
wherein an operating speed of the first memory region is faster than an operating speed of the second memory region.

2. The semiconductor device of claim 1, wherein the logic region, the first memory region, and the second memory region are included in a single chip.

3. The semiconductor device of claim 1, further comprising:
a package substrate, at least one chip including the logic region, the first memory region, and the second memory region being on the package substrate.

4. The semiconductor device of claim 3, wherein the logic region is included in a first chip, the first memory region is included in a second chip, the second memory region is included in a third chip, and
wherein the first chip is on a first surface of the package substrate, and the second chip and the third chip are on a second surface of the package substrate facing the first surface.

5. The semiconductor device of claim 3, wherein the logic region is included in a first chip, the first memory region and the second memory region are included in a second chip, and
wherein the first chip is on a first surface of the package substrate, and the second chip is on a second surface of the package substrate facing the first surface.

6. The semiconductor device of claim 1, wherein the logic region comprises:
a front end of line (FEOL) region comprising semiconductor elements on a semiconductor substrate; and
a back end of line (BEOL) region comprising wiring patterns connecting at least some of the semiconductor elements to each other,
wherein the logic region comprises a first region and a second region in different locations in a direction parallel to an upper surface of the semiconductor substrate,
wherein a density of the wiring patterns in the BEOL region of the first region is higher than a density of the wiring patterns in the BEOL region of the second region, and
wherein the first region is closer to the second memory region than the first memory region.

7. The semiconductor device of claim 6, wherein at least one of a central processing unit (CPU), a graphics processing unit (GPU), and a neural processor is in the first region, and at least one of an input/output circuit and a power circuit is in the second region.

8. The semiconductor device of claim 1, wherein each of the plurality of first memory cells is a first spin transfer torque (STT)-magnetoresistive random-access memory (MRAM) cell comprising a first magnetic memory element, and each of the plurality of second memory cells is a second STT MRAM cell comprising a second magnetic memory element, and
wherein a perpendicular magnetic anisotropy of the first magnetic memory element is lower than a perpendicular magnetic anisotropy of the second magnetic memory element.

9. The semiconductor device of claim 8, wherein a size of each of the plurality of first memory cells is smaller than a size of each of the plurality of second memory cells.

10. The semiconductor device of claim 1, wherein each of the plurality of first memory cells is a spin orbit torque (SOT)-MRAM cell, and each of the plurality of second memory cells is an STT-MRAM cell.

11. The semiconductor device of claim 1, wherein each of the plurality of first memory cells is an STT-MRAM cell or an SOT-MRAM cell, and each of the plurality of second memory cells is a racetrack memory cell.

12. A semiconductor device comprising:
a logic region comprising a semiconductor substrate, a front end of line (FEOL) region comprising semiconductor elements on the semiconductor substrate, and a back end of line (BEOL) region comprising wiring patterns connecting at least some of the semiconductor elements to each other;
a first memory region comprising a plurality of first memory cells; and
a second memory region comprising a plurality of second memory cells different from the plurality of first memory cells,
wherein the logic region comprising a first region and a second region in different locations in a direction parallel to an upper surface of the semiconductor substrate,
wherein a density of the wiring patterns in the BEOL region in the first region is higher than a density of the wiring patterns in the BEOL region in the second region, and
wherein the first region is closer to the first memory region than the second memory region.

13. The semiconductor device of claim 12, wherein a structure of the plurality of first memory cells is the same as a structure of the plurality of second memory cells, and a size of each of the plurality of first memory cells is smaller than a size of each of the plurality of second memory cells.

14. The semiconductor device of claim 12, wherein a structure of the plurality of first memory cells have a structure is different from a structure of the plurality of second memory cells.

15. The semiconductor device of claim 14, wherein each of the plurality of first memory cells comprises a switch element and a first magnetic memory element, and
wherein each of the plurality of second memory cells comprises a second magnetic memory element.

16. The semiconductor device of claim 12, wherein an integration density of the first memory region is lower than an integration density of the second memory region.

17. A semiconductor device comprising:
a logic region comprising a core that comprises a plurality of intellectual property (IP) blocks, and a plurality of cache memories;
a first memory region being a dynamic memory; and
a second memory region being a storage and having a storage capacity greater than a storage capacity of the first memory region,
wherein the plurality of cache memories comprise an L1 cache, an L2 cache, and an L3 cache, and the L3 cache, and
wherein the first memory region and the second memory region are a magnetic memory device.

18. The semiconductor device of claim 17, wherein each of a plurality of memory cells included in the L3 cache is a spin transfer torque (STT)-magnetoresistive random-access memory (MRAM) cell.

19. The semiconductor device of claim 17, wherein the L2 cache is provided by the magnetic memory device.

20. The semiconductor device of claim 19, wherein a structure of each of a plurality of memory cells included in the second memory region is different from a structure of each of a plurality of memory cells included in the L2 cache.

21. (canceled)
